(19) United States
(12) Patent Application Publication
(10) Pub. No.: US 2025/0062703 A1
(43) Pub. Date: Feb. 20, 2025

(54) POWER GENERATING APPARATUS WITH IMPROVED EFFICIENCY USING RESONANCE

(71) Applicant: Sang-Cheol Bae, Daegu (KR)

(72) Inventor: Sang-Cheol Bae, Daegu (KR)

(21) Appl. No.: 18/494,577

(22) Filed: Oct. 25, 2023

(30) Foreign Application Priority Data
Aug. 14, 2023 (KR) 10-2023-0106390

(51) Int. Cl. H02N 2/18; H10N 30/30; H10N 30/88

(52) U.S. Cl. CPC H02N 2/188; H10N 30/30; H10N 30/88

(57) ABSTRACT

A power generating apparatus with improved efficiency using resonance, the apparatus comprising: a base part with cylindrical shape; and a piezoelectric part disposed on an outer side surface of the base part; wherein the piezoelectric part including at least one piezoelectric element generating electricity using vibration generated by the base part.

### CROSS-REFERENCE TO RELATED APPLICATIONS

This application claims priority under 35 U.S.C § 119 to Korean Patent Application No. 10-2023-0106390, filed on 14 Aug. 2023, in the Korean Intellectual Property Office, the entire disclosure of which is incorporated herein by reference in its entirety.

### FIELD OF THE INVENTION

Embodiments of the invention relate to power generating apparatus with improved efficiency using resonance.

### DISCUSSION OF RELATED ART

Recently, interest in eco-friendly renewable energy technology is increasing.

Among renewable energy technologies, power generation technology using vibration has recently been actively researched and developed.

### SUMMARY OF THE INVENTION

The present invention is directed to power generating apparatus with improved efficiency using resonance, the apparatus comprising: a base part with cylindrical shape; and a piezoelectric part disposed on an outer side surface of the base part; wherein the piezoelectric part including at least one piezoelectric element generating electricity using vibration generated by the base part.

The present invention is directed to power generating apparatus with improved efficiency using resonance, the apparatus comprising: a first base part with cylindrical shape; a second base part with cylindrical shape; and a piezoelectric part disposed on an outer side surface of each of the first base part and the second base part; wherein the piezoelectric part including at least one piezoelectric element generating electricity using vibration generated by the first base part or the second base part, wherein one end of the first base part and the second base part are open and the other end of the first base part and the second base part are blocked, further comprising a first cover part covering the other end of the first base part and a second cover part covering the other end of the second base part, wherein one end of the first base part and one end of the second base part face each other.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram for explaining the configuration of a power generating apparatus with improved efficiency using resonance according to the present invention.

FIG. 2A, FIG. 2B and FIG. 3A, FIG. 3B, FIG. 4A, FIG. 4B, FIG. 5A, FIG. 5B, FIG. 6A, FIG. 6B, FIG. 7A, FIG. 7B, FIG. 8, FIG. 9A, FIG. 9B, FIG. 10A, FIG. 10B, FIG. 11A, FIG. 11B and FIG. 12A, FIG. 12B are diagrams for explaining in detail the base part and the piezoelectric part.

FIG. 13 and FIG. 14 are diagrams for explaining in detail the vibration generating means and parts related thereto.

FIG. 15A, FIG. 15B and FIG. 16 are diagrams for explaining in detail the cover part, pillar part and parts related thereto.

FIG. 17, FIG. 18A, FIG. 18B and FIG. 19 are diagrams for explaining another configuration of the power generating apparatus with improved efficiency using resonance according to the present invention.

### DETAILED DESCRIPTION OF EXEMPLARY EMBODIMENTS

In order to describe the present disclosure, operational advantages of the present disclosure, and purposes achieved by embodiments of the present disclosure, hereinafter, preferable embodiments of the present disclosure will be described and the present disclosure will be examined with reference to the preferable embodiments.

First, terms used in the present disclosure are used only to describe the particular embodiments and not to limit the present disclosure, and the singular form may be intended to also include the plural form, unless the context clearly indicates otherwise. Further, it should be further understood that the terms “include,” “including,” “provide,” “providing,” “have,” and/or “having” specify the presence of stated features, integers, steps, operations, elements, components, and/or groups thereof but do not preclude the presence or addition of one or more other features, integers, steps, operations, elements, components, and/or groups thereof.

In a description of the present disclosure, when specific descriptions such as related known functions or configurations related to the present disclosure unnecessarily obscure the spirit of the present disclosure, a detailed description of the specific descriptions will be omitted.

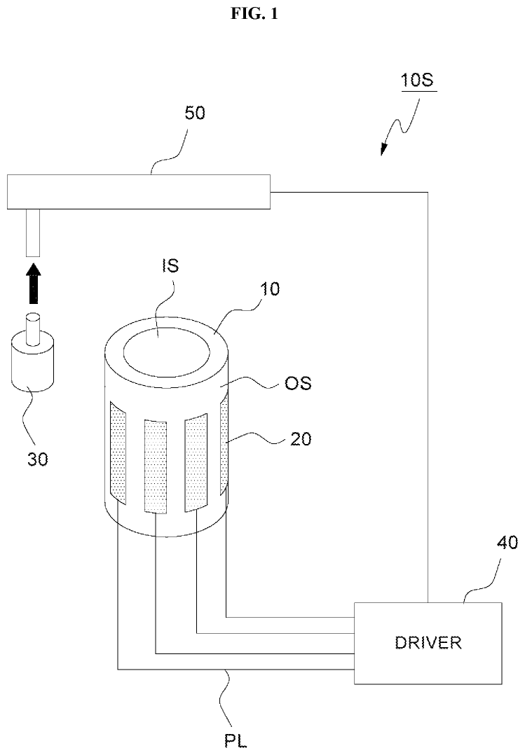

FIG. 1 is a diagram for explaining the configuration of a power generating apparatus with improved efficiency using resonance according to the present invention.

Referring to FIG. 1, a power generating apparatus 10S according to the present invention may include a base part 10 and a piezoelectric part 20.

And, the power generating apparatus 10S may further include at least one of vibration generating means 30, driver 40 or arm part 50.

The base part 10 may have cylindrical shape.

Preferably, the base part 10 may include metal material such as aluminum or copper.

The piezoelectric part 20 may disposed on outer side surface OS of the base part 10.

The piezoelectric part 20 may include at least one piezoelectric element generating electricity using vibration generated by the base part 10.

The vibration generating means 30 may apply at least one of rubbing and striking on the base part 10 to generate vibration of the base part 10.

The arm part 50 may drive the vibration generating means 30 under the control of the driver 40.

The driver 40 may control the arm part 50 to apply friction and/or impact to the base part 10.

The driver 40 may store electricity generated by the piezoelectric part 20 using vibration of the base part 10 or supply it to a system.

To this end, the driver 40 may receive electricity from the piezoelectric part 20 through a power line PL.

An identification code IS not described in FIG. 1 may indicate an inner side surface corresponding to the outer surface OS of the base part 10.

When the vibration generating means 30 applies impact and/or friction to the base part 10, the base part 10 may vibrate.

Herein, the base part 10 may resonate in response to the vibration frequency.

Accordingly, the vibration of the base part 10 does not disappear within a short time, but may be maintained for a sufficiently long time while gradually weakening.

Then, the amount of electricity generated by the piezoelectric part 20 using the vibration of the base part 10 may increase.

Thereafter, the driver 40 may receive and store the electricity generated by the piezoelectric part 20 or supply it to the system.

Hereinafter, each part of the power generating apparatus 10S according to the present invention will be described in detail.

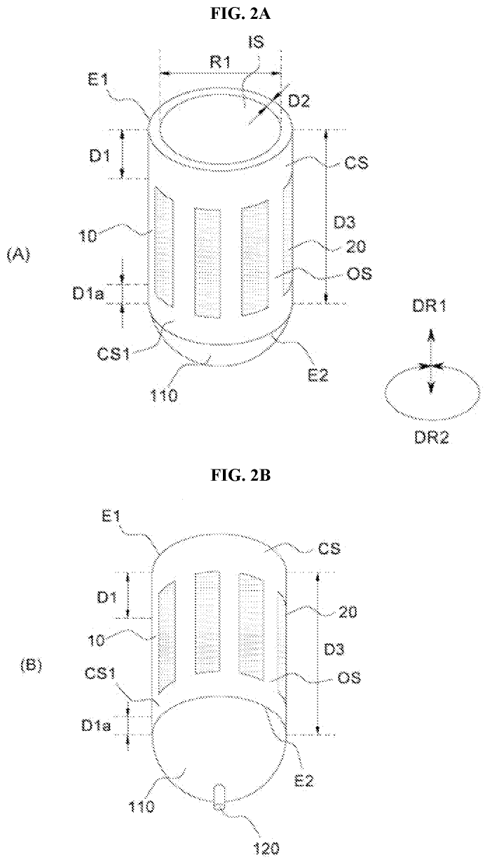

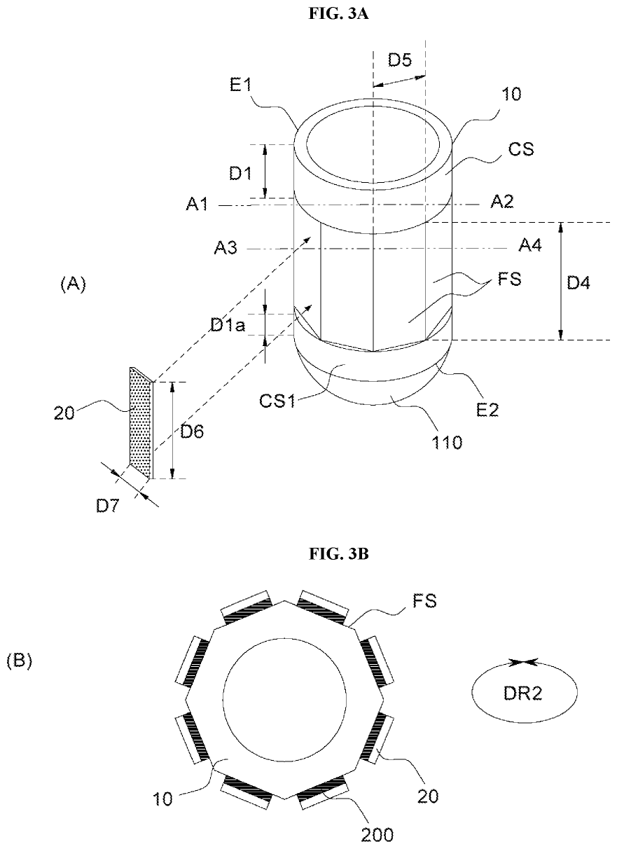

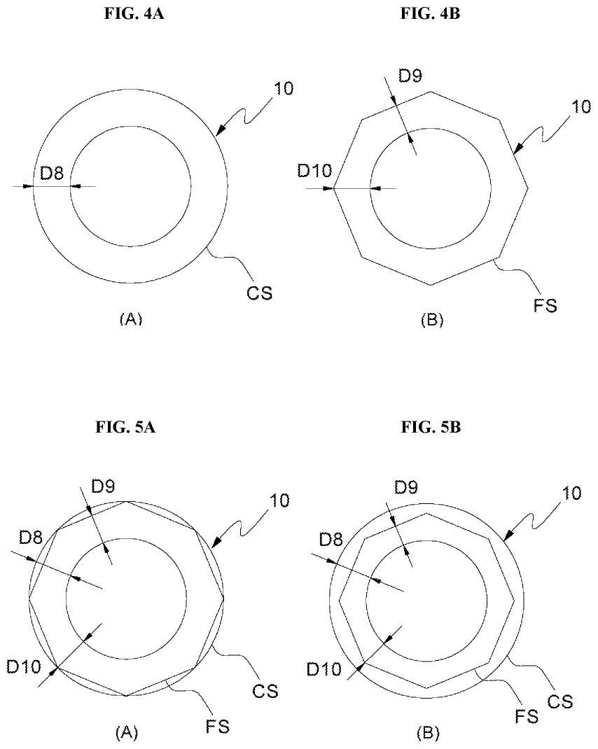

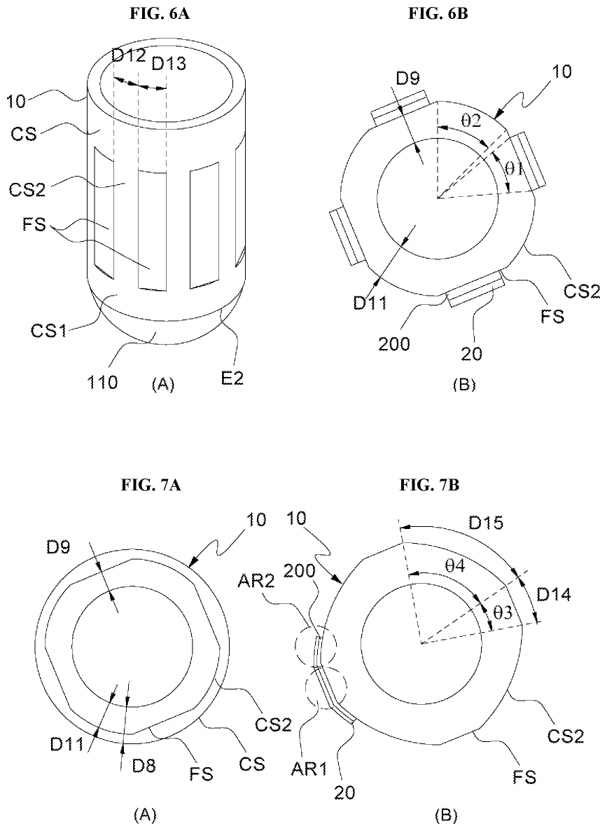

FIGS. 2 to 12 are diagrams for explaining in detail the base part and the piezoelectric part. Hereinafter, description of the parts described in detail above may be omitted.

Referring to FIG. 2, the base part 10 has cylindrical shape in which one end E1 of the base part 10 is open and the other end E2 of the base part 10 is blocked.

To this end, the power generating apparatus 10S according to the present invention may further include a cover part 110 covering the other end E2 of the base part 10.

The cover part 110 has a convexly protruding shape toward the rear in a longitudinal direction DR1.

The cover part 110 may include same material to the base part 10.

The cover part 110 may be connected to the other end E2 of the base part 10.

Alternatively, the cover part 110 and the base part 10 may be integrally formed to form a single body.

The cover part 10 may have hemispheric shape.

The power generating apparatus 10S according to the present invention may further include a pillar part 120.

One end of the pillar part 120 may be connected to a central portion of the cover part 110.

The other end of the pillar part 120 may be connected to a supporting part (not shown).

In order for the base part 10 to resonate sufficiently effectively in response to the vibration frequency, an inner diameter R1 of the base part 10, a length D3 of the base part 10 in the longitudinal direction DR1, and an average wall thickness D2 of the base part 10 may be appropriately adjusted.

Preferably, a ratio of the inner diameter R1 of the base part 10 and the length of the base part 10 in the longitudinal direction DR1 is 1:0.5˜1:2.

More preferably, the ratio of the inner diameter R1 of the base part 10 and the length of the base part 10 in the longitudinal direction DR1 is 1:0.8˜1:1.3.

Preferably, a ratio of the inner diameter R1 of the base part 10 and average wall thickness D2 of the base part 10 is 200:1˜5:1.

More preferably, the ratio of the inner diameter R1 of the base part 10 and average wall thickness D2 of the base part 10 is 100:1˜20:1.

A plurality of the piezoelectric parts 20 may be disposed on the outer surface OS of the base part 10 in a circumferential direction DR2 of the base part 10.

The piezoelectric part 20 and one end E1 of the base part 10 may be spaced apart from each other by predetermined distance D1 in the longitudinal direction DR1 of the base part 10.

In the longitudinal direction DR1 of the base part 10, a curved surface CS may be disposed between the piezoelectric part 20 and one end E1 of the base part 10.

In addition, the piezoelectric part 20 and the other end E2 of the base part 10 may be spaced apart from each other by predetermined distance D1a in the longitudinal direction DR1 of the base part 10.

In the longitudinal direction DR1 of the base part 10, another curved surface CS1 may be disposed between the piezoelectric part 20 and the other end E2 of the base part 10.

In the longitudinal direction DR1 of the base part 10, the distance D1 between the piezoelectric part 20 and one end E1 of the base part 10 may greater than the distance D1a between the piezoelectric part 20 and the other end E2 of the base part 10.

Referring to FIG. 3, the base part 10 may include at least one flat surface FS on the outer side surface OS of the base part 10.

A plurality of the flat surface FS may be disposed on the outer surface OS of the base part 10 in the circumferential direction DR2 of the base part 10.

The piezoelectric part 20 may be disposed on the flat surface FS.

In this case, the curved surface CS may be located between the flat surface FS and one end E1 of the base part 10 in the longitudinal direction DR1 of the base part 10.

The curved surface CS may have smooth surface.

Herein, length of the flat surface FS in the longitudinal direction DR1 of the base part 10 may greater than width of the flat surface 10 in the circumferential direction DR2 of the base part 10.

Length of the piezoelectric part 20 in the longitudinal direction DR1 of the base part 10 may greater than width of the piezoelectric part 20 in the circumferential direction DR2 of the base part 10.

An adhesive layer 200 may be disposed between the flat surface FS and the piezoelectric part 20 for attaching the piezoelectric part 20 to the base part 10.

The adhesive layer 20 may include epoxy material.

The piezoelectric part 20 may be fixed to the flat surface FS by the adhesive layer 200.

A view in which the base part 10 is cut along the line A1-A2 corresponding to the curved surface CS is shown in FIG. 4(A).

Referring to FIG. 4(A), the base part 10 has a constant wall thickness D8 in a region corresponding to the curved surface CS.

In addition, a view in which the base part 10 is cut along the line A3-A4 corresponding to the flat surface FS is shown in FIG. 4(B).

Referring to FIG. 4(B), the base part 10 has a varying wall thickness in a region corresponding to the flat surface FS.

In the region corresponding to the flat surface FS, the base part 10 has minimum wall thickness D9 at a portion corresponding to a center of the flat part FS in the circumferential direction DR2 of the base part 10.

Average wall thickness of the base part 10 in the region corresponding to the flat surface FS may less than wall thickness (D10) of the base part 10 in a region between two flat surfaces FS.

Referring to FIG. 5(A), wall thickness D8 of the base part 10 in the region corresponding to the curved surface CS may equal to maximum wall thickness D10 of the base part 10 in the region corresponding to the flat surface FS.

Referring to FIG. 5(B), wall thickness D8 of the base part 10 in the region corresponding to the curved surface CS may greater than maximum wall thickness D10 of the base part 10 in the region corresponding to the flat surface FS.

Referring to FIG. 6, in the circumferential direction DR2 of the base part 10, the other curved surface CS2 may be disposed between two adjacent piezoelectric parts 20.

The base part 10 has a constant wall thickness D11 in a region corresponding to the other curved surface CS2.

In the circumferential direction DR2 of the base part 10, a width D12 of the other curved surface CS2 may less than a width D13 of the flat surface FS.

From another point of view, based on the center of the base part 10, an angle θ2 corresponding to the other curved surface CS2 may be smaller than an angle θ1 corresponding to the flat surface FS.

Referring to FIG. 7(A), wall thickness D11 of the base part 10 in the region corresponding to the other curved surface CS2 may less than wall thickness D8 of the base part 10 in the region corresponding to the curved surface CS.

Referring to FIG. 7(B), unlike the previous case of FIG. 6(A), in the circumferential direction DR2 of the base part 10, a width D15 of the other curved surface CS2 may greater than a width D14 of the flat surface FS.

From another point of view, based on the center of the base part 10, an angle θ4 corresponding to the other curved surface CS2 may be greater than an angle θ3 corresponding to the flat surface FS.

In this case, the adhesive layer 200 may correspond to the flat surface FS in a first area AR1, and may correspond to the other curved surface CS2 in a second area AR2 located on both sides of the first area AR1.

In addition, the piezoelectric part 20 may correspond to the flat surface FS in the first area AR1 and may correspond to the other curved surface CS2 in the second area AR2.

Referring to FIG. 8, another curved surface CS1 between the flat surface FS and the other end E2 of the base part 10 in the longitudinal direction DR1 may be omitted.

In this case, the flat surface FS may be adjacent to the cover part 110.

Referring to FIG. 9, plurality of protruders 130 with convex shape are disposed on the curved surface CS.

In this case, the area of a contact surface of the base part 10 with respect to the vibration generating means 30 may be increased.

Referring to FIG. 10, the curved surface CS of the base part 10 may include a plurality of grooves 140 extending in the longitudinal direction DR1 and recessed to a predetermined depth.

A peak 141 extending in the longitudinal direction DR1 may be disposed between two adjacent grooves 140.

A diameter of the base part 10 in a region corresponding to the groove 140 may be less than a diameter of the base part 10 in a region corresponding to the peak 141.

Referring to FIG. 11, a depression part 150 having a concave shape may be formed on the flat surface FS of the base part 10.

The depression part 150 may include a portion extending along the longitudinal direction DR1 of the base portion 10.

Another flat surface FS1 may be provided within the depression 150.

The piezoelectric part 20 may be disposed on the another flat surface FS1 within the depression part 150.

A length D16 of the depression part 150 in the longitudinal direction DR1 of the base part 10 may less than length D4 of the flat surface FS in the longitudinal direction DR1 of the base part 10.

A width D17 of the depression part 150 in the circumferential direction DR2 of the base part 10 may less than width of the flat surface FS in the circumferential direction DR2 of the base part 10.

The piezoelectric part 20 may correspond to a portion having the minimum wall thickness D9 in the base part 10.

In this case, it is possible to resonate the base part 10 more easily.

Referring to FIG. 12(A), the width D17 of the depression part 150 in the circumferential direction DR2 of the base part 10 may be smaller than a distance D18 between two adjacent depression part 150.

The minimum wall thickness D9 of the base part 10 may be smaller than average depth D19 of the depression part 150.

Referring to FIG. 12(B), the power generating apparatus 10S according to the present invention may further include a protective layer 210 covering the piezoelectric part 20 disposed within the depression part 150.

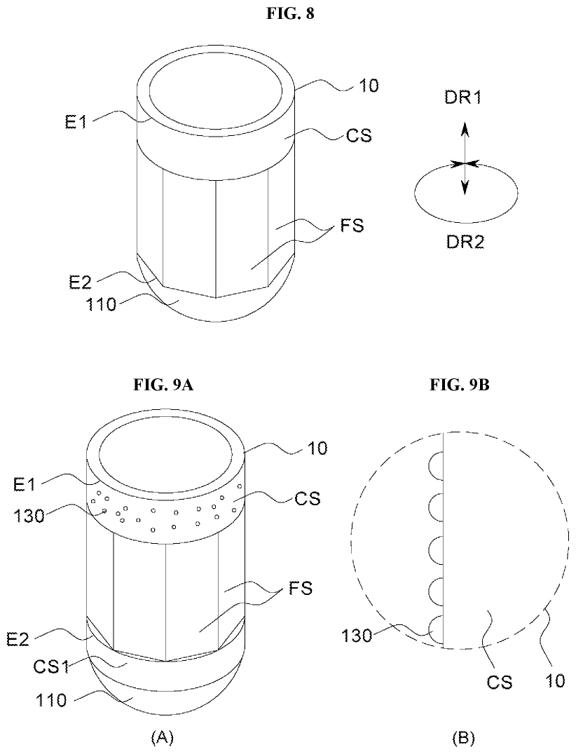

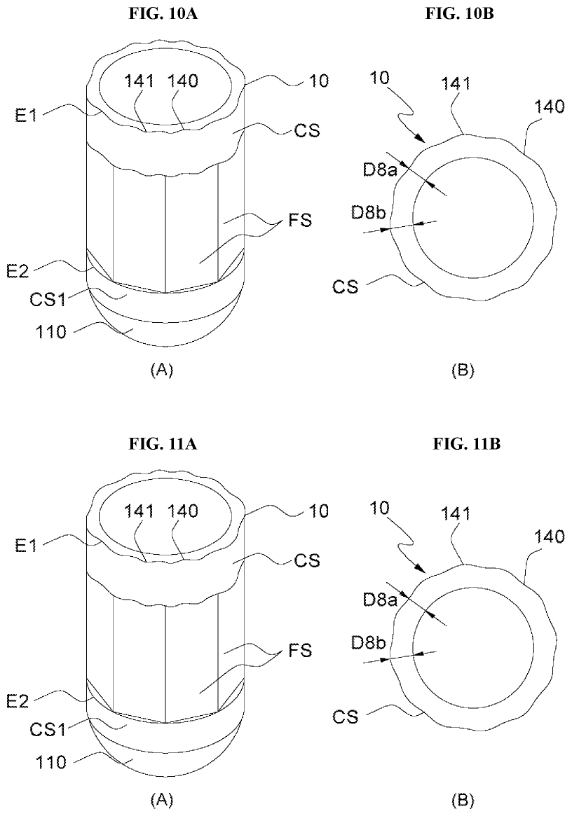

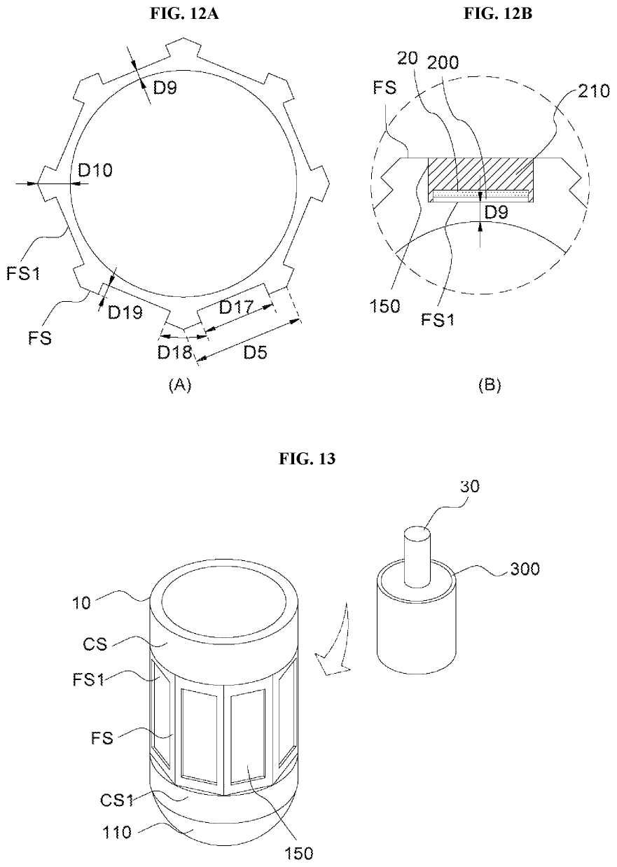

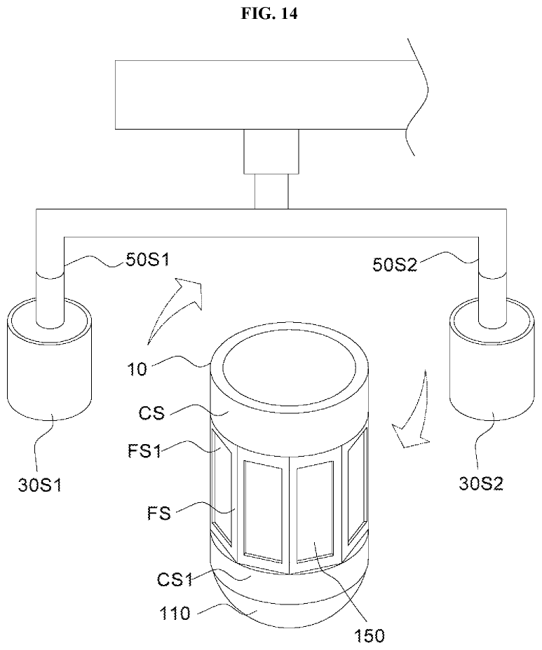

FIGS. 13 to 14 are diagrams for explaining in detail the vibration generating means and parts related thereto. Hereinafter, description of the parts described in detail above may be omitted.

Referring to FIG. 13, the vibration generating means 30 may apply at least one of rubbing and striking on the curved surface CS to generate vibration of the base part 10.

For example, the vibration generating means 30 may rotate or reciprocate along the curved surface CS of the base part 10 in a state of being in contact with the curved surface CS.

For more effective vibration generation, a portion 300 of the vibration generating means 30 contacting to the curved surface CS may include a material that is softer than the base part 10.

The portion 300 of the vibration generating means 30 contacting to the curved surface CS may include a leather material, synthetic resin material, PC (Poly Carbonate) material and/or rubber material.

A plurality of vibration generating means 30 may be applied to single base part 10.

For example, as shown in FIG. 14, a first sub-vibration generating means 30S1 and a second sub-vibration generating means 30S2 may be applied to single base part 10.

The arm part 50 may include a first sub-arm part 50S1, a second sub-arm part 50S2, and a rotating part 500.

One end of the first sub-arm part 50S1 may be connected to the first sub-vibration generating means 30S1, and one end of the second sub-arm part 50S2 may be connected to the second sub-vibration generating means 30S2.

Another end of the first sub-arm part 50S1 may be connected to the rotating part 500, and another end of the second sub-arm part 50S2 may be connected to the rotating part 500.

The base part 10 may be disposed between the first sub-arm part 50S1 and the second sub-arm part 50S2.

The rotating part 500 may rotate in a state in which the first sub-arm part 50S1 and the second sub-arm part 50S2 are in contact with the curved surface CS of the base part 10, respectively.

In this case, the base part 10 may generate vibration by the first sub-arm part 50S1 and the second sub-arm part 50S2.

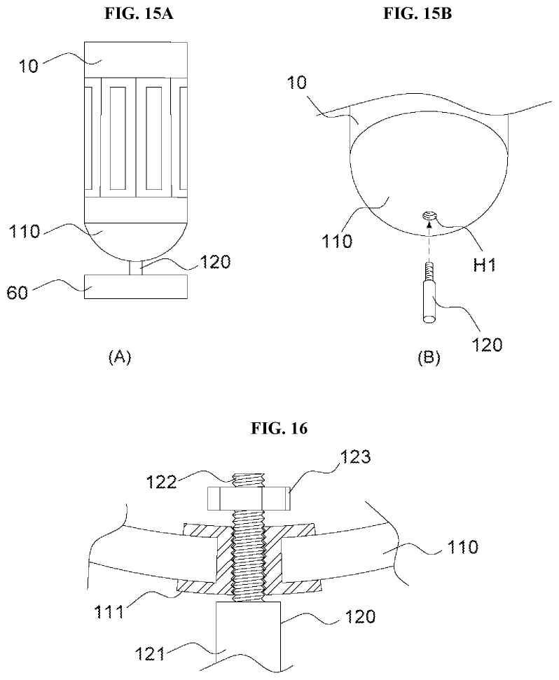

FIGS. 15 to 16 are diagrams for explaining in detail the cover part, pillar part and parts related thereto. Hereinafter, description of the parts described in detail above may be omitted.

Referring to FIG. 15(A), the other end of the pillar part 120 may be connected to a supporting part 60.

Referring to FIG. 15(B), the cover part 110 further includes a first hole H1 formed in the central portion of the cover part 110.

The pillar part 120 may support the cover part 110.

The pillar part 120 may include a portion inserted into the first hole H1 to fasten the pillar part 120 to the cover part 110.

Referring to FIG. 16, the power generating apparatus 10S according to the present invention may further include a buffer part 111 including a portion located in side wall of the first hole H1.

The buffer part 111 may include a material that is softer than the cover part 110.

For example, the buffer part 111 may include the rubber material, the synthetic resin material, and/or a plastic material.

A thread may be formed on the surface of the buffer part 111.

The pillar part 120 may include a pillar body part 121, a first part 122 in which a thread is formed, and a nut part 123 fastened to the first part 122.

The first part 122 of the pillar part 120 may be inserted into the first hole H1 while being engaged with the thread of the buffer part 111.

In this case, the base part 10 may be vibrated more effectively.

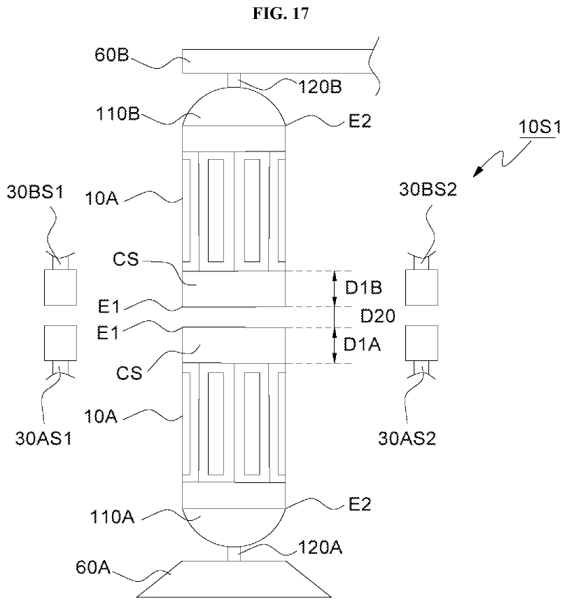

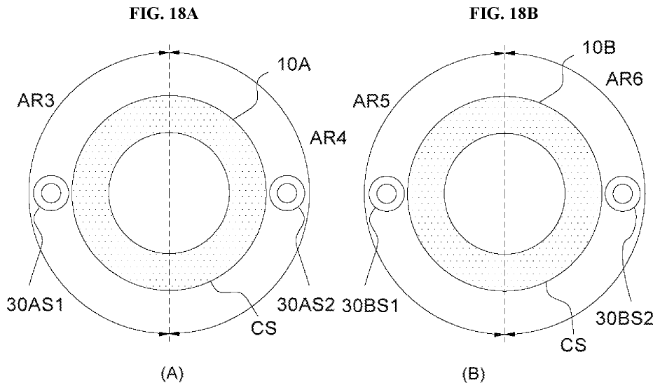

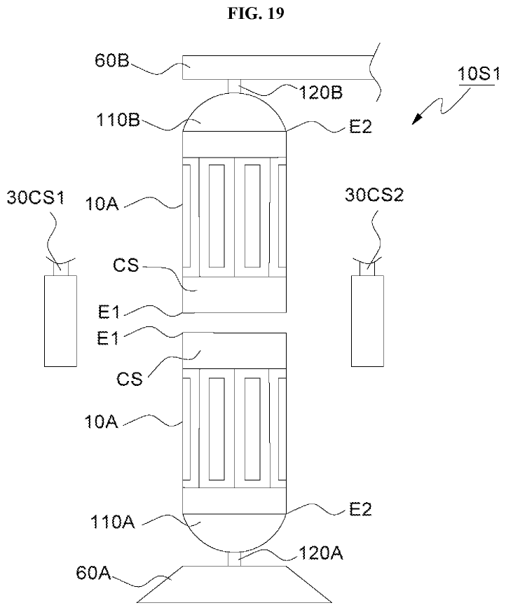

FIGS. 17 to 19 are diagrams for explaining another configuration of the power generating apparatus with improved efficiency using resonance according to the present invention. Hereinafter, description of the parts described in detail above may be omitted.

Referring to FIG. 17, another power generating apparatus 10S1 according to the present invention may include a first base part 10A, a second base part 10B, the piezoelectric part 20, a first cover part 110A, and a second cover part 110B.

Each of the first base part 10A and the second base part 10B may have the cylindrical shape.

The piezoelectric part 20 may include at least one piezoelectric element disposed on outer surfaces of the first base part 10A and the second base part 10B and generating electricity by vibration generated by the first base part 10A or the second base part 10B.

One end E1 of the first base part 10A and the second base part 10B may be open and the other end E2 may be blocked.

The first cover part 110A may block the other end E2 of the first base part 10A, and the second cover part 110B may block the other end E2 of the second base part 10B.

Herein, one end E1 of the first base part 10A and one end E1 of the second base part 10B may face each other.

Another power generating apparatus 10S1 according to the present invention may further include a first pillar part 120A, a first supporting part 60A, a second pillar part 120B, and a second supporting part 60B.

One end of the first pillar part 120A may be connected to a central portion of the first cover part 110A.

The other end of the first pillar part 120A may be connected to the first supporting part 60A.

One end of the second pillar part 120B may be connected to a central portion of the second cover part 110B.

The other end of the second pillar part 120B may be connected to the second supporting part 60B.

Herein, the first supporting part 60A may be disposed on ground, and the second supporting part 60B may be disposed above the first supporting part 60A.

Corresponding to the first base part 10A, a 1st-1st sub-vibration generating means 30AS1 and a 2nd-1st sub-vibration generating means 30AS2 may be applied.

Corresponding to the second base part 10B, a 1st-2nd sub-vibration generating means 30BS1 and a 2nd-2nd sub-vibration generating means 30BS2 may be applied.

In this case, the vibration generated in the first base part 10A may be transferred to the second base part 10B, so that the vibration of the second base part 10B may be amplified.

And, the vibration generated in the second base part 10B may be transferred to the first base part 10A, so that the vibration of the first base part 10A may be amplified.

The distance D20 between the first base part 10A and the second base part 10B may be smaller than a lengths D1A and D1B of the curved surfaces CS in the longitudinal direction DR1 of the first base part 10A and the second base part 10B.

Referring to FIG. 18, the 1st-1st sub-vibration generating means 30AS1 may reciprocate in a third area AR3 in a state of contact with the curved surface CS of the first base part 10A.

The 2nd-1st sub-vibration generating means 30AS2 may reciprocate in a fourth area AR4 in a state of contact with the curved surface CS of the first base part 10A.

In this way, the 1st-1st sub-vibration generating means 30AS1 and the 2nd-1st sub-vibration generating means 30AS2 may generate vibration by applying friction to the curved surface CS of the first base part 10A.

The 1st-2nd sub-vibration generating means 30BS1 may reciprocate in a fifth area AR5 in a state of contact with the curved surface CS of the second base part 10B.

The 2nd-2nd sub-vibration generating means 30BS2 may reciprocate in a sixth area AR6 in a state of contact with the curved surface CS of the second base part 10B.

In this way, the 1st-2nd sub-vibration generating means 30BS1 and the 2nd-2nd sub-vibration generating means 30BS2 may generate vibration by applying friction to the curved surface CS of the second base part 10B.

Referring to FIG. 19, the 1st-1st sub-vibration generating means 30AS1 and the 2nd-1st sub-vibration generating means 30AS2 may be integrated into a first common vibration generating means 30CS1.

The first common vibration generating means 30CS1 may generate vibration by applying friction to the curved surfaces CS in the third area AR3 of the first base part 10A and the fifth area AR5 of the second base part 10B.

The 1st-2nd sub-vibration generating means 30BS1 and the 2nd-2nd sub-vibration generating means 30BS2 may be integrated into a second common vibration generating means 30CS2.

The second common vibration generating means 30CS2 may generate vibration by applying friction to the curved surfaces CS in the fourth area AR4 of the first base part 10A and the sixth area AR6 of the second base part 10B.

As described above, the present disclosure is described with reference to one embodiment shown in the drawings but is only an example, and it may be understood that various modifications and other equivalents may be performed by those skilled in the art.

Accordingly, a technical scope of the present disclosure should be determined by a technical spirit of the appended claims.

What is claimed is:

1. Power generating apparatus with improved efficiency using resonance, the apparatus comprising:
a base part with cylindrical shape; and
a piezoelectric part disposed on an outer side surface of the base part;
wherein the piezoelectric part including at least one piezoelectric element generating electricity using vibration generated by the base part.

2. The apparatus of claim 1, wherein the base part includes metal material.

3. The apparatus of claim 1, wherein one end of the base part is open and the other end of the base part is blocked.

4. The apparatus of claim 3, further comprising a cover part covering the other end of the base part,
wherein the cover part has a convexly protruding shape.

5. The apparatus of claim 4, further comprising a pillar part connected to a central portion of the cover part,
wherein the pillar part is connected to a supporting part.

6. The apparatus of claim 1, wherein the base part includes at least one flat surface on the outer side surface,
wherein the piezoelectric part is disposed on the flat surface.

7. The apparatus of claim 6, wherein the base part further includes a curved surface disposed between the flat surface and one end of the base part in a longitudinal direction of the base part.

8. The apparatus of claim 7, further comprising a vibration generating means applying at least one of rubbing and striking on the curved surface to generate vibration of the base part.

9. The apparatus of claim 8, wherein a portion of the vibration generating means contacting to the curved surface includes a material that is softer than the base part.

10. The apparatus of claim 7, wherein the base part has a constant wall thickness in a region corresponding to the curved surface.

11. The apparatus of claim 6, wherein average wall thickness of the base part in a region corresponding to the flat surface is less than wall thickness of the base part in a region between two flat surfaces.

12. The apparatus of claim 11, wherein the base part has a varying wall thickness in the region corresponding to the flat surface.

13. The apparatus of claim 7, wherein plurality of a protruders with convex shape are disposed on the curved surface.

14. The apparatus of claim 6, wherein length of the flat surface in a longitudinal direction of the base part is greater than width of the flat surface in a circumferential direction of the base part.

15. The apparatus of claim 14, wherein length of the piezoelectric part in the longitudinal direction of the base part is greater than width of the piezoelectric part in the circumferential direction of the base part.

16. The apparatus of claim 6, wherein further comprising an adhesive layer disposed between the flat surface and the piezoelectric part for attaching the piezoelectric part to the base part.

17. The apparatus of claim 6, wherein a depression part with concave shape is formed on the flat surface,
wherein the depression part is extended along a longitudinal direction of the base part,
wherein the piezoelectric part is disposed within the depression part.

18. The apparatus of claim 17, wherein length of the depression part in the longitudinal direction of the base part is less than length of the flat surface in the longitudinal direction of the base part.

19. Power generating apparatus with improved efficiency using resonance, the apparatus comprising:
a first base part with cylindrical shape;
a second base part with cylindrical shape; and
a piezoelectric part disposed on an outer side surface of each of the first base part and the second base part;
wherein the piezoelectric part including at least one piezoelectric element generating electricity using vibration generated by the first base part or the second base part,
wherein one end of the first base part and the second base part are open and the other end of the first base part and the second base part are blocked,
further comprising a first cover part covering the other end of the first base part and a second cover part covering the other end of the second base part,
wherein one end of the first base part and one end of the second base part face each other.

20. The apparatus of claim 19, further comprising:
a first pillar part connected to a central portion of the first cover part;
a first supporting part;
a second pillar part connected to a central portion of the second cover part; and
a second supporting part;
wherein one end of the first pillar part is connected to the central portion of the first cover part,
wherein the other end of the first pillar part is connected to the first supporting part,
wherein one end of the second pillar part is connected to the central portion of the second cover part,
wherein the other end of the second pillar part is connected to the second supporting part.
